(19) United States
(12) Patent Application Publication
(10) Pub. No.: US 2017/0253995 A1
(43) Pub. Date: Sep. 7, 2017

(54) METHOD FOR HEAT-TREATING SILICON SINGLE CRYSTAL WAFER

(71) Applicant: SHIN-ETSU HANDOTAI CO., LTD., Tokyo (JP)

(72) Inventors: Wei Feng QU, Takasaki (JP); Fumio TAHARA, Annaka (JP); Masahiro SAKURADA, Annaka (JP); Shuji TAKAHASHI, Tomioka (JP)

(73) Assignee: SHIN-ETSU HANDOTAI CO., LTD., Tokyo (JP)

(21) Appl. No.: 15/519,859

(22) PCT Filed: Sep. 17, 2015
(86) PCT No.: PCT/JP2015/004761

§ 371 Date: Apr. 18, 2017

(30) Foreign Application Priority Data
Nov. 26, 2014 (JP) 2014-238308

(51) Int. Cl. C30B 33/02; H01L 21/322; C30B 29/06

(52) U.S. Cl. CPC C30B 33/02; C30B 29/06; H01L 21/3225

(57) ABSTRACT

A method for heat-treating a silicon single crystal wafer by an RTA treatment, including: putting a silicon single crystal wafer having an Nv region for the entire plane of the silicon single crystal wafer or an Nv region containing an OSF region for the silicon single crystal wafer entire plane into an RTA furnace, performing pre-heating at temperature lower than temperature at which silicon reacts with NH3 while supplying gas that contains NH3 into the RTA furnace, subsequently stopping the supply of the gas containing NH3 and starting supply of Ar gas to start an RTA treatment under Ar gas atmosphere in which the NH3 gas remains. This provide a method for heat-treating a silicon single crystal wafer that give gettering capability without degrading TDDB properties even to a silicon single crystal wafer in which the entire plane is an Nv region or an Nv region containing an OSF region.

### TECHNICAL FIELD

The present invention relates to a method for heat-treating a silicon single crystal wafer.

### BACKGROUND ART

Rapid Thermal Annealing (RTA) treatment has been performed previously to provide silicon single crystal wafers with gettering capability.

Such RTA treatment has been widely applied to a silicon single crystal wafer in which the entire plane is a neutral (hereinafter, also referred to as an N) region having almost equal quantities of vacancies, which are point defects (Vacancy; hereinafter, also referred to as Va), and interstitial point defects called Interstitial Silicon (hereinafter, also referred to as I-Si). More specifically, this has been applied to wafers having an Ni region in which I-Si is dominant, Nv region in which Va is dominant, and Nv region that contains an Oxidation induced Stacking Faults (OSF) region for the entire plane of each wafer as the N region.

As an example of such RTA treatment, Patent Document 1 describes a method to bring gettering capability by performing RTA treatment under an NH₃-containing atmosphere to form a nitride film on a wafer surface to provide vacancies for a wafer. However, when such a method is used for RTA treatment of a silicon single crystal wafer in which the entire plane is an Nv region or an Nv region containing an OSF region, the wafer can have larger BMD size and excessively higher BMD density in accordance with the oxygen concentration of the wafer, and the Time Dependent Dielectric Breakdown (TDDB) properties are degraded thereby.

### CITATION LIST

### Patent Document

Patent Document 1: Japanese Unexamined Patent Application publication (Kokai) No. 2009-212537

### SUMMARY OF INVENTION

### Problem to be Solved by the Invention

The present invention was accomplished to solve the above-described problems. It is an object of the present invention to provide a method for heat-treating a silicon single crystal wafer that can give gettering capability without degrading TDDB properties even to a silicon single crystal wafer having an Nv region for the entire plane of the silicon single crystal wafer or an Nv region that contains an OSF region for the entire plane of the silicon single crystal wafer.

### Means for Solving Problem

To solve the above-described problems, the present invention provides a method for heat-treating a silicon single crystal wafer by a rapid thermal annealing treatment, comprising:

putting a silicon single crystal wafer having an Nv region for the entire plane of the silicon single crystal wafer or an Nv region that contains an OSF region for the entire plane of the silicon single crystal wafer into a rapid thermal annealing furnace,

performing pre-heating at a temperature lower than the temperature at which silicon reacts with NH₃ while supplying gas that contains NH₃ into the rapid thermal annealing furnace, and subsequently

stopping the supply of the gas that contains NH₃ and starting supply of Ar gas to start a rapid thermal annealing treatment under Ar gas atmosphere in which the NH₃ gas remains.

Such a heat-treating method can make a nitride film formed on the surface of a silicon single crystal wafer have a film thickness thinner than that formed by a previous method. This can suppress the amount of supplied vacancies, which makes it possible to prevent excessive oxygen precipitation to prevent generation of oxide precipitates onto the surface portion even in a silicon single crystal wafer in which the entire plane is an Nv region or an Nv region containing an OSF region. Accordingly, it is possible to give gettering capability without degrading TDDB properties.

It is preferable that the rapid thermal annealing (RTA) treatment be performed under conditions of 1,000 to 1,275° C. for 10 to 30 seconds.

The RTA treatment under such conditions makes it easy to appropriately implant vacancies, which makes it possible to give gettering capability more securely. It is also possible to prevent occurrence of slip dislocation and contamination of heavy metals from devices.

The pre-heating is preferably performed at a temperature that is higher than ordinary temperature and is 600° C. or less.

The pre-heating at such a temperature makes the NH₃ concentration in a furnace be uniform, which makes it possible to prevent formation of a nitride film in the pre-heating more securely.

It is also preferable that the silicon single crystal wafer have an Nv region for the entire plane of the silicon single crystal wafer and have an oxygen concentration of 10 to 12 ppma; or the silicon single crystal wafer have an Nv region that contains an OSF region for the entire plane of the silicon single crystal wafer and have an oxygen concentration of 9 to 11 ppma.

The inventive heat-treating method is particularly effective in heat treatment of a silicon single crystal wafer with such an oxygen concentration. The inventive heat-treating method can improve TDDB properties and give gettering capability concurrently and more securely even though the oxygen concentration is in such a range.

In the rapid thermal annealing (RTA) treatment, an NH₃ concentration in the rapid thermal annealing furnace is preferably set to 0.5% by volume or more and 3% by volume or less when heated to the temperature at which silicon reacts with NH₃.

When the NH₃ concentration in an RTA furnace is such a concentration, it is possible to form a nitride film having uniform film thicknesses in the wafer plane more securely.

### Effect of Invention

As described above, the inventive method for heat-treating a silicon single crystal wafer can give gettering capability without degrading TDDB properties even to a silicon single crystal wafer having an Nv region for the entire plane of the silicon single crystal wafer or an Nv region that contains an OSF region for the entire plane of the silicon single crystal wafer.

Accordingly, the inventive method for heat-treating a silicon single crystal wafer can form a Denuded Zone (DZ) layer without generating a crystal defect from the wafer surface to a certain depth of activated region of a device. It is also possible to obtain a silicon single crystal wafer that can form oxide precipitates, which can be gettering sites, in the wafer by heat-treating for oxygen precipitation, etc.

### BRIEF DESCRIPTION OF DRAWINGS

FIG. 1 is a flow diagram showing an example of the inventive method for heat-treating a silicon single crystal wafer;

FIG. 2 is a graph showing the thicknesses of nitride films to compare a nitride film formed by the inventive heat-treating method and a nitride film formed by a previous heat-treating method;

FIG. 3 is a graph of TDDB (γ mode) obtained from measured values of each wafer, the entire plane of which is an Nv region that contains an OSF region, subjected to heat treatment by the heat-treating method of Example 1 or Comparative Example 1;

FIG. 4 is a graph of BMD densities obtained from measured values of each wafer, the entire plane of which is an Nv region that contains an OSF region, subjected to heat treatment by the heat-treating method of Example 1 or Comparative Example 1.

### DESCRIPTION OF EMBODIMENTS

In a silicon single crystal wafer in which the entire plane is an Ni region, RTA treatment in an NH₃ atmosphere does not promote formation of BMD, and does not degrade the TDDB properties thereby. On the other hand, in a silicon single crystal wafer in which the entire plane is an Nv region or an Nv region containing an OSF region, RTA treatment in an NH₃ atmosphere causes to promote formation of BMD when the oxygen concentration is high to a certain degree. This generates oxide precipitates onto the surface portion to degrade the TDDB properties.

Accordingly, the inventors have conceived that a silicon single crystal wafer in which the entire plane is an Nv region or an Nv region containing an OSF region can be provided with gettering capability without degrading the TDDB properties by thinning the thickness of a nitride film formed on the wafer surface to suppress amount of supplied vacancies in RTA treatment in NH₃-containing atmosphere.

Specifically, the inventors have found that a thinner nitride film can be formed by supplying NH₃-containing gas, which have been supplied in both of pre-heating and RTA treatment in previous arts, in the pre-heating only, and controlling the temperature so as not to form a nitride film in the pre-heating, and by performing the subsequent RTA treatment in which the NH₃-containing gas supply is stopped and the gas to be supplied is changed to Ar gas, whereby forming a thin nitride film from the gas that contains NH₃ supplied in the pre-heating and remained in the RTA furnace; thereby brought the present invention to completion.

That is, the present invention is a method for heat-treating a silicon single crystal wafer by a rapid thermal annealing treatment, comprising:

putting a silicon single crystal wafer having an Nv region for the entire plane of the silicon single crystal wafer or an Nv region that contains an OSF region for the entire plane of the silicon single crystal wafer into a rapid thermal annealing furnace,

performing pre-heating at a temperature lower than the temperature at which silicon reacts with NH₃ while supplying gas that contains NH₃ into the rapid thermal annealing furnace, and subsequently

stopping the supply of the gas that contains NH₃ and starting supply of Ar gas to start a rapid thermal annealing treatment under Ar gas atmosphere in which the NH₃ gas remains.

Hereinafter, the present invention will be more specifically described, but the present invention is not limited thereto.

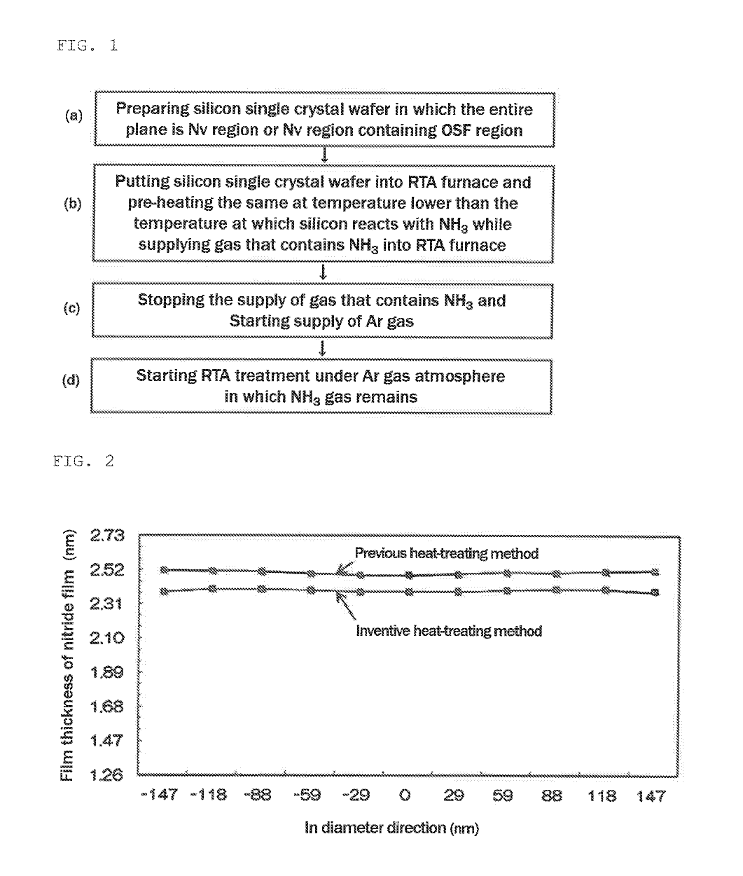

FIG. 1 is a flow diagram showing an example of the inventive method for heat-treating a silicon single crystal wafer.

In the heat-treating method of FIG. 1, first, a silicon single crystal wafer in which the entire plane is an Nv region or an Nv region containing an OSF region is prepared (FIG. 1 (a)). Then, this silicon single crystal wafer is put into an RTA furnace and subjected to pre-heating at a temperature lower than the temperature at which silicon reacts with NH₃ while supplying NH₃-containing gas into the RTA furnace (FIG. 1 (b)). Subsequently, the NH₃-containing gas supply is stopped, Ar gas supply is started (FIG. 1 (c)), and an RTA treatment is started under Ar gas atmosphere in which the NH₃ gas remains to perform the RTA treatment (FIG. 1 (d)).

In the inventive heat-treating method, the temperature is controlled to a temperature lower than the temperature at which silicon reacts with NH₃ in the pre-heating to supply NH₃-containing gas. Accordingly, a nitride film is not formed on a wafer surface before the RTA treatment. Since the NH₃-containing gas is supplied only in the pre-heating, and the RTA treatment is performed after stopping the NH₃-containing gas supply and starting Ar gas supply, the NH₃-containing gas remained in the RTA furnace is uniformly diffused in the furnace by concentration gradient to decrease the NH₃ concentration in the furnace. The uniformly diffused NH₃-containing gas (nitriding gas) reacts with silicon during the temperature raising and holding at higher temperature in the RTA treatment to form a nitride film with a thin and uniform film thickness. As a result, it is possible to suppress the amount of vacancies implanted by the RTA treatment to decrease an effect of promoting oxide precipitation compared to previous heat-treating methods, in which NH₃-containing gas is continuously supplied through the whole process (both of pre-heating and RTA treatment), to prevent generation of the oxide precipitates on the surface portion.

Hereinafter, the present invention will be more specifically described.

### [Silicon Single Crystal Wafer]

The inventive heat-treating method directs to a silicon single crystal wafer having an Nv region for the entire plane of the silicon single crystal wafer or an Nv region that contains an OSF region for the entire plane of the silicon single crystal wafer. Such a wafer can be sliced from a silicon single crystal produced by a Czochralski method, for example. In a wafer having such a defect region, as described above, the TDDB properties are degraded by previous heat-treating, in which NH₃-containing gas is supplied in both of pre-heating and RTA treatment. The inventive heat-treating method, however, can provide gettering capability without degrading the TDDB properties even to such a wafer.

The silicon single crystal wafer is preferably a silicon single crystal wafer having an Nv region for the entire plane of the silicon single crystal wafer and having an oxygen concentration of 10 to 12 ppma, or a silicon single crystal wafer having an Nv region that contains an OSF region for the entire plane of the silicon single crystal wafer and having an oxygen concentration of 9 to 11 ppma. The inventive heat-treating method is particularly effective in heat-treating of a silicon single crystal wafer having such an oxygen concentration. It is possible to prevent degradation of the TDDB properties more securely, while forming the BMD density in an appropriate range.

Incidentally, in the present invention, “ppma” refers to “ppma (JEITA)” (using a conversion factor of Japan Electronics and Information Technology Industries Association (JEITA)).

### [Pre-Heating]

Subsequently, the silicon single crystal wafer is put into an RTA furnace, and subjected to pre-heating at a temperature lower than the temperature at which silicon reacts with NH₃ while supplying NH₃-containing gas into the RTA furnace. In this stage, the heating temperature is set to a temperature lower than the temperature at which silicon reacts with NH₃, preferably a temperature that is higher than ordinary temperature and is 600° C. or less, whereby a nitride film is not formed on a wafer surface in the pre-heating.

In the inventive heat-treating method, the thickness of the nitride film formed in the RTA treatment is almost independent of the conditions in the pre-heating such as heating temperature, heating time, and flow rate of NH₃-containing gas as far as the heating temperature in the pre-heating is at the foregoing temperature. Accordingly, the conditions of the pre-heating is not particularly limited, and can be set to a heating temperature that is higher than ordinary temperature (about 25° C.) and is 600° C. or less, heating time of 10 to 60 seconds, and flow rate of NH₃-containing gas of 0.1 to 5 L/min.

As the NH₃-containing gas, which is not particularly limited, Ar gas that contains NH₃ can be preferably used, for example. As will be described later, in the RTA treatment in the present invention, it is preferable that the NH₃ concentration in the RTA furnace be set to 0.5% by volume or more and 3% by volume or less when heated to the temperature at which silicon reacts with NH₃. Accordingly, the NH₃ concentration of the NH₃-containing gas supplied in the pre-heating is preferably a concentration such that the NH₃ concentration in the RTA furnace in the RTA treatment is in the range described above, more specifically, 1% by volume or more and 6.5% by volume or less, for example.

### [Stopping NH₃-Containing Gas Supply and Starting Ar Gas Supply]

After performing the pre-heating, stopping the supply of the NH₃-containing gas and starting supply of Ar gas are performed. At this stage, the stopping of NH₃-containing gas supply and the starting of Ar gas supply may be performed in either order, and can be performed simultaneously. Moreover, the stopping of NH₃-containing gas supply and the starting of Ar gas supply may be performed prior to the starting of RTA treatment described later, and can be performed simultaneously with the starting of RTA treatment.

### [RTA Treatment]

Then, the RTA treatment is started under Ar gas atmosphere in which the NH₃ gas remains. Incidentally, in the inventive heat-treating method including the step of the stopping of NH₃-containing gas supply and the starting of Ar gas supply, the NH₃ concentration in the RTA furnace is not limited when the temperature is raised to the temperature at which silicon reacts with NH₃ in the RTA treatment. However, by setting this concentration to 0.5% by volume or more and 3% by volume or less, particularly, it becomes easier to form the nitride films to have the same thickness even though the conditions of the RTA treatment such as the temperature, the time, and the flow rate of Ar gas are different. Accordingly, the condition of the RTA treatment is not particularly limited. However, it is preferable to perform the RTA treatment under the condition such as the heating temperature of 1,000 to 1,275° C. and the heating time of 10 to 30 seconds, since this can give gettering capability more securely. This can also prevent generation of slip dislocation and contamination of heavy metals.

With regard to this, the thicknesses of a nitride film formed by the previous heat-treating method and a nitride film formed by the inventive heat-treating method were compared to give the results shown in FIG. 2. Incidentally, as the previous heat-treating method, pre-heating was performed at 210 to 350° C. for 10 seconds while supplying Ar gas that contained 3% by volume of NH₃, and then RTA treatment was performed at the maximum temperature of 1,175° C. for 10 seconds while supplying Ar gas that contained 3% by volume of NH₃. On the other hand, in the inventive heat-treating method, pre-heating was performed in the same manner as in the previous heat-treating method, followed by stopping the NH₃-containing Ar gas supply, starting Ar gas supply, and RTA treatment that was performed at the same temperature and time as in the previous heat-treating method.

As shown in FIG. 2, the nitride film formed by the previous heat-treating method had a thickness of about 2.5 nm. On the other hand, the nitride film formed by the inventive heat-treating method had a thickness of about 2.4 nm, which is thinner about 0.1 nm. This slight difference of nitride film thicknesses largely influences to the amount of implanted vacancies in the RTA treatment. Accordingly, with the nitride film formed by the inventive heat-treating method to have a thickness thinner than the previous ones, it is possible to effectively suppress the amount of implanted vacancies to suppress formation of oxygen precipitates on the wafer surface.

The inventors have further investigated to found that the nitride film can be more securely formed to have a film thickness that is uniform in the plane by setting the NH₃ concentration to be 0.5% by volume or more and 3% by volume or less as the NH₃ concentration in an RTA furnace when the temperature is raised to the temperature at which silicon reacts with NH₃ in the inventive heat-treating method. It was also revealed that the uniformity of film thickness of the nitride film is largely dependent on the foregoing NH₃ concentration in a RTA furnace in the RTA treatment, and is almost independent of the other conditions of pre-heating and RTA treatment.

The TDDB properties, the BMD size, and the BMD density were evaluated on a wafer heat-treated by the previous heat-treating method in which NH₃-containing gas had been continuously supplied in both of the pre-heating and the RTA treatment to reveal that the TDDB properties are particularly preferable when the BMD size is 22 nm or less and the BMD density is 3×10⁹/cm³ or less. On the other hand, it was found that the wafer can have particularly preferable gettering capability when the BMD density is 5×10⁸/cm³ or more, particularly 1×10⁹/cm³ or more. This reveals that a wafer with the BMD size of 22 nm or less and the BMD density of 1×10⁹/cm³ to 3×10⁹/cm³ can be a wafer having particularly preferable TDDB properties and gettering capability.

The inventive heat-treating method can suppress the amount of supplied vacancies to give a wafer having preferable BMD size and BMD density described above, and can give a wafer having particularly preferable TDDB properties and gettering capability thereby.

As described above, in the inventive method for heat-treating a silicon single crystal wafer, the temperature in the pre-heating is controlled so as not to form a nitride film, and the nitride film is formed from NH₃ gas remained in an RTA furnace in the RTA treatment. Accordingly, it is possible to thin the thickness of a nitride film formed on a wafer surface by an RTA treatment in comparison to the previous heat-treating methods. This makes it possible to suppress the amount of supplied vacancies to give gettering capability, without degrading the TDDB properties, even to a silicon single crystal wafer having an Nv region for the entire plane of the silicon single crystal wafer or an Nv region that contains an OSF region for the entire plane of the silicon single crystal wafer, in which the TDDB properties are degraded by the previous heat-treating method.

### Example

Hereinafter, the present invention will be specifically described by using Example, Comparative Example, and Reference Example, but the present invention is not limited thereto.

### (Silicon Single Crystal Wafer)

As silicon single crystal wafers to be subjected to heat-treating of Example 1 and Comparative Example 1, silicon single crystal wafers in which each entire plane was an Nv region and silicon single crystal wafers in which each entire plane was an Nv region containing an OSF region were prepared with each oxygen concentration being varied. These wafers were each prepared to have oxygen concentrations of 6.0 ppma, 8.0 ppma, 9.0 ppma, 10.0 ppma, 11.0 ppma, 12.0 ppma, and 14.0 ppma.

### Example 1

The prepared wafers were subjected to the pre-heating under the following conditions. Subsequently, NH₃-containing gas supply was stopped and Ar gas supply was started, and then the RTA treatment was performed under the following conditions in Ar gas atmosphere in which the NH₃ gas remained.

### (Conditions of Pre-Heating)

heat-treating temperature: 350° C. or less
heat-treating time: 10 seconds
gas supplied: Ar gas that contained 3% by volume of NH₃
amount of gas supply: 0.6 L/min

### (Conditions of RTA Treatment)

heat-treating temperature (maximum temperature): 1,175° C.
heat-treating time: 10 seconds
gas supplied: Ar gas
amount of gas supply: 20 L/min
NH₃ concentration in RTA furnace (NH₃ concentration in RTA furnace when the temperature is increased to the temperature at which silicon reacts with NH₃ (600° C.)): 0.6% by volume

### Comparative Example 1

The prepared wafers were subjected to the pre-heating under the following conditions. Subsequently, RTA treatment was performed under the following conditions while continuing the NH₃-containing gas supply.

### (Conditions of Pre-Heating)

heat-treating temperature: 350° C. or less
heat-treating time: 10 seconds
gas supplied: Ar gas that contained 3% by volume of NH₃
amount of gas supply: 0.6 L/min

### (Conditions of RTA Treatment)

heat-treating temperature (maximum temperature): 1,175° C.
heat-treating time: 10 seconds
gas supplied: Ar gas that contained 3% by volume of NH₃
amount of gas supply: 20 L/min
NH₃ concentration in RTA furnace: 3% by volume (supplied continuously)

Subsequently, the TDDB properties and the BMD density were evaluated as follows on each wafer subjected to heat treatment by the heat-treating method of Example 1 or Comparative Example 1 described above.

### (Evaluation of TDDB Properties)

Each TDDB (γ mode) was measured under the conditions of the thickness of gate oxide layer: 25 nm, the electrode area: 4 mm², and the criterion of TDDB (γ mode): 5 C/cm² or more, and evaluated on the basis of the following criteria.

Good: 93%≦TDDB (γ mode)
Fair: 80%≦TDDB (γ mode)<93%
Bad: TDDB (γ mode)<80%

### (Evaluation of BMD Density)

Each wafer was subjected to oxygen precipitation treatment at 800° C. for 4 hours and 1,000° C. for 16 hours, cleaved, and etched. The BMD density at the cleaved surface was measured and evaluated on the basis of the following criteria.

Excellent: 3×10⁹/cm³≦BMD density
Good: 1×10⁹/cm³≦BMD density<3×10⁹/cm³
Fair: 5×10⁸/cm³≦BMD density<1×10⁹/cm³
Bad: BMD density<5×10⁸/cm³

The evaluation results of each silicon single crystal wafer in which the entire plane was an Nv region are shown in Table 1, and the evaluation results of each silicon single crystal wafer in which the entire plane was an Nv region containing an OSF region are shown in Table 2.

TABLE 1
Silicon single crystal wafer in which the entire plane was Nv region

| | Heat-treating | | Heat-treating | |
|---|---|---|---|---|
| | method in | | method in | |
| Oxygen | Example 1 | | Comparative Example 1 | |
| concentration Oi | TDDB | | TDDB | |
| (ppma) | property | BMD density | property | BMD density |
| 6.0 | Good | Fair | Good | Fair |
| 8.0 | Good | Good | Good | Good |
| 9.0 | Good | Good | Fair | Good |
| 10.0 | Good | Good | Fair | Excellent |
| 11.0 | Good | Good | Bad | Excellent |
| 12.0 | Good | Excellent | Bad | Excellent |
| 14.0 | Fair | Excellent | Bad | Excellent |

TABLE 2
Silicon single crystal wafer in which the entire plane was Nv region
containing OSF region

| | Heat-treating | | Heat-treating | |
|---|---|---|---|---|
| | method in | | method in | |
| Oxygen | Example 1 | | Comparative Example 1 | |
| concentration Oi | TDDB | | TDDB | |
| (ppma) | property | BMD density | property | BMD density |
| 6.0 | Good | Fair | Good | Fair |
| 8.0 | Good | Good | Good | Good |
| 9.0 | Good | Good | Good | Good |
| 10.0 | Good | Good | Good | Excellent |
| 11.0 | Good | Good | Fair | Excellent |
| 12.0 | Fair | Excellent | Fair | Excellent |
| 14.0 | Bad | Excellent | Bad | Excellent |

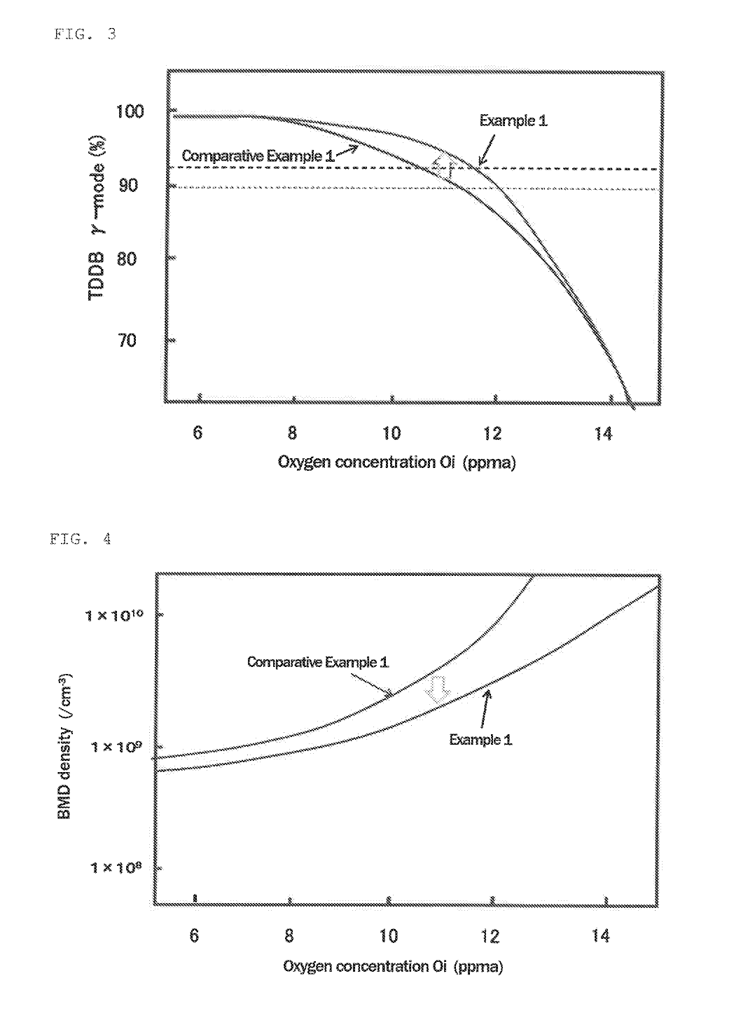

On the basis of the measured values of each wafer, in which the entire plane was an Nv region containing an OSF region, and the heat treatment was performed by the heat-treating method of Example 1 or Comparative Example 1 as described above, the graph of TDDB (γ mode) and the graph of the BMD densities were obtained, which are shown in FIG. 3 and FIG. 4, respectively.

### Reference Example 1

As wafers for Reference Example, silicon single crystal wafers in which each entire plane was an Ni region, differed from Example 1 and Comparative Example 1, were prepared. These wafers were each prepared to have oxygen concentrations of 6.0 ppma, 8.0 ppma, 9.0 ppma, 10.0 ppma, 11.0 ppma, 12.0 ppma, and 14.0 ppma.

The prepared wafers were subjected to the pre-heating followed by the RTA treatment under the same conditions as in each of Example 1 and Comparative Example 1. The TDDB properties and the BMD densities of the obtained wafers were evaluated in the same manner as in Example 1. The results are shown in Table 3.

TABLE 3
Silicon single crystal wafer in which the entire plane was Ni region

| | Heat-treating | | Heat-treating | |
|---|---|---|---|---|
| | method in | | method in | |
| Oxygen | Example 1 | | Comparative Example 1 | |
| concentration Oi | TDDB | | TDDB | |
| (ppma) | property | BMD density | property | BMD density |
| 6.0 | Good | Bad | Good | Bad |
| 8.0 | Good | Bad | Good | Bad |
| 9.0 | Good | Fair | Good | Fair |
| 10.0 | Good | Fair | Good | Fair |
| 11.0 | Good | Good | Good | Good |
| 12.0 | Good | Good | Good | Good |
| 14.0 | Good | Good | Good | Good |

As shown in Tables 1 and 2, and FIGS. 3 and 4, it was found that the heat treatment by the heat-treating method of Example 1 can decrease the BMD densities entirely and can suppress degradation of the TDDB properties compared to the heat treatment by the heat-treating method of Comparative Example 1 while ensuring the BMD densities to the extent of having gettering capability. Particularly, in silicon single crystal wafers in which each entire plane was an Nv region, the TDDB properties were remarkably improved when the oxygen concentrations were 10 to 12 ppma; in silicon single crystal wafers in which each entire plane was an Nv region containing OSF region, the TDDB properties were remarkably improved when the oxygen concentrations were 9 to 11 ppma. In the foregoing oxygen concentration, the BMD densities were particularly preferable, and the excellent gettering capability could be obtained.

On the other hand, in silicon single crystal wafers in which each entire plane was an Ni region, the pre-heating and RTA treatment of Example 1 and Comparative Example 1 did not show substantial difference in the BMD densities and the TDDB properties as shown in Table 3.

Accordingly, Example 1, Comparative Example 1, and Reference Example 1 have revealed that the present invention realizes extremely high effect on the improvement of TDDB properties when the heat treatment is directed to a silicon single crystal wafer in which the entire plane is an Nv region or the entire plane is an Nv region containing an OSF region as in the present invention.

From the foregoing results, it can be revealed that the inventive method for heat-treating a silicon single crystal wafer can control the BMD density to an appropriate value without degrading the TDDB properties even in a silicon single crystal wafer in which the entire plane is an Nv region or the entire plane is an Nv region containing an OSF region, and accordingly, can produce a silicon single crystal wafer having gettering capability with the DZ layer being ensured to have excellent TDDB properties.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1-6. (canceled)

7. A method for heat-treating a silicon single crystal wafer by a rapid thermal annealing treatment, comprising:
putting a silicon single crystal wafer having an Nv region for the entire plane of the silicon single crystal wafer or an Nv region that contains an OSF region for the entire plane of the silicon single crystal wafer into a rapid thermal annealing furnace,
performing pre-heating at a temperature lower than the temperature at which silicon reacts with NH₃ while supplying gas that contains NH₃ into the rapid thermal annealing furnace, and subsequently
stopping the supply of the gas that contains NH₃ and starting supply of Ar gas to start a rapid thermal annealing treatment under Ar gas atmosphere in which the NH₃ gas remains.

8. The method for heat-treating a silicon single crystal wafer according to claim 7, wherein the rapid thermal annealing treatment is performed under conditions of 1,000 to 1,275° C. for 10 to 30 seconds.

9. The method for heat-treating a silicon single crystal wafer according to claim 7, wherein the pre-heating is performed at a temperature that is higher than ordinary temperature and is 600° C. or less.

10. The method for heat-treating a silicon single crystal wafer according to claim 8, wherein the pre-heating is performed at a temperature that is higher than ordinary temperature and is 600° C. or less.

11. The method for heat-treating a silicon single crystal wafer according to claim 7, wherein the silicon single crystal wafer has an Nv region for the entire plane of the silicon single crystal wafer and has an oxygen concentration of 10 to 12 ppma.

12. The method for heat-treating a silicon single crystal wafer according to claim 8, wherein the silicon single crystal wafer has an Nv region for the entire plane of the silicon single crystal wafer and has an oxygen concentration of 10 to 12 ppma.

13. The method for heat-treating a silicon single crystal wafer according to claim 9, wherein the silicon single crystal wafer has an Nv region for the entire plane of the silicon single crystal wafer and has an oxygen concentration of 10 to 12 ppma.

14. The method for heat-treating a silicon single crystal wafer according to claim 10, wherein the silicon single crystal wafer has an Nv region for the entire plane of the silicon single crystal wafer and has an oxygen concentration of 10 to 12 ppma.

15. The method for heat-treating a silicon single crystal wafer according to claim 7, wherein the silicon single crystal wafer has an Nv region that contains an OSF region for the entire plane of the silicon single crystal wafer and has an oxygen concentration of 9 to 11 ppma.

16. The method for heat-treating a silicon single crystal wafer according to claim 8, wherein the silicon single crystal wafer has an Nv region that contains an OSF region for the entire plane of the silicon single crystal wafer and has an oxygen concentration of 9 to 11 ppma.

17. The method for heat-treating a silicon single crystal wafer according to claim 9, wherein the silicon single crystal wafer has an Nv region that contains an OSF region for the entire plane of the silicon single crystal wafer and has an oxygen concentration of 9 to 11 ppma.

18. The method for heat-treating a silicon single crystal wafer according to claim 10, wherein the silicon single crystal wafer has an Nv region that contains an OSF region for the entire plane of the silicon single crystal wafer and has an oxygen concentration of 9 to 11 ppma.

19. The method for heat-treating a silicon single crystal wafer according to claim 7, wherein, in the rapid thermal annealing treatment, an NH₃ concentration in the rapid thermal annealing furnace is set to 0.5% by volume or more and 3% by volume or less when heated to the temperature at which silicon reacts with NH₃.

20. The method for heat-treating a silicon single crystal wafer according to claim 8, wherein, in the rapid thermal annealing treatment, an NH₃ concentration in the rapid thermal annealing furnace is set to 0.5% by volume or more and 3% by volume or less when heated to the temperature at which silicon reacts with NH₃.

21. The method for heat-treating a silicon single crystal wafer according to claim 9, wherein, in the rapid thermal annealing treatment, an NH₃ concentration in the rapid thermal annealing furnace is set to 0.5% by volume or more and 3% by volume or less when heated to the temperature at which silicon reacts with NH₃.

22. The method for heat-treating a silicon single crystal wafer according to claim 11, wherein, in the rapid thermal annealing treatment, an NH₃ concentration in the rapid thermal annealing furnace is set to 0.5% by volume or more and 3% by volume or less when heated to the temperature at which silicon reacts with NH₃.

23. The method for heat-treating a silicon single crystal wafer according to claim 15, wherein, in the rapid thermal annealing treatment, an NH₃ concentration in the rapid thermal annealing furnace is set to 0.5% by volume or more and 3% by volume or less when heated to the temperature at which silicon reacts with NH₃.
